(19) United States
(12) Patent Application Publication
(10) Pub. No.: US 2026/0068549 A1
(43) Pub. Date: Mar. 5, 2026

(54) SEMICONDUCTOR DEVICE AND MANUFACTURING METHOD OF SEMICONDUCTOR DEVICE

(71) Applicant: SK hynix Inc., Icheon-si (KR)

(72) Inventors: Sang Chul OH, Icheon-si (KR); Myoungsub KIM, Icheon-si (KR); Jae Hyuk PARK, Icheon-si (KR); Beom Seok LEE, Icheon-si (KR); Won Jun LEE, Icheon-si (KR)

(21) Appl. No.: 19/185,657

(22) Filed: Apr. 22, 2025

(30) Foreign Application Priority Data
Sep. 4, 2024 (KR) 10-2024-0120273

(51) Int. Cl. H10N 70/00; H10B 63/00

(52) U.S. Cl. CPC H10N 70/8833; H10B 63/80; H10N 70/023; H10N 70/028; H10N 70/063; H10N 70/841

(57) ABSTRACT

A semiconductor device may include: a stack including electrode plates and insulating layers that are alternately stacked; an electrode pillar extending through the stack; a variable resistance layer surrounding a sidewall of the electrode pillar; and first electrodes located between the electrode plates and the variable resistance layer, respectively, and each including metal oxide.

### CROSS-REFERENCE TO RELATED APPLICATION

This application claims priority under 35 U.S.C. § 119 to Korean Patent Application No. 10-2024-0120273 filed on Sep. 4, 2024, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

Recently, in accordance with miniaturization, low power consumption, performance improvement, diversification, and the like, of electronic devices, semiconductor devices capable of storing information have been demanded in various electronic devices such as computers and portable communication devices. Accordingly, research into a semiconductor device capable of storing data using characteristics of switching between different resistance states depending on an applied voltage or current has been conducted. Examples of such a semiconductor device include a resistive random access memory (RRAM), a phase-change random access memory (PRAM), a ferroelectric random access memory (FRAM), a magnetic random access memory (MRAM), and the like.

### SUMMARY

In an embodiment, a semiconductor device may include: a stack including electrode plates and insulating layers that are alternately stacked; an electrode pillar extending through the stack; a variable resistance layer provided over a sidewall of the electrode pillar and extending through the electrode plates and the insulating layers; and first electrodes located between the electrode plates and the variable resistance layer, respectively, and each including metal oxide.

In an embodiment, a semiconductor device may include: a plurality of memory cells that are stacked along a direction, each memory cell including a first electrode and a second electrode, the first electrode including metal oxide; an electrode pillar extending along the direction and through the plurality of the memory cells; and a variable resistance layer provided over a sidewall of the electrode pillar and shared by the memory cells, the variable resistance layer extending between the first and the second electrodes of the memory cells; and a first electrode provided over the variable resistance layer and shared by the memory cells, wherein the first electrode includes metal oxide.

In an embodiment, a method for manufacturing a semiconductor device may include: forming a stack including electrode plates and insulating layers that are alternately stacked; forming a first opening extending through the stack to expose the electrode plates; forming first electrodes on or over the exposed electrode plates, the first electrodes each including metal oxide; forming a variable resistance layer in the first opening; and forming an electrode pillar in the variable resistance layer.

In an embodiment, a method for manufacturing a semiconductor device may include: forming a stack including sacrificial layers and insulating layers that are alternately stacked; forming a first opening extending through the stack; forming a first electrode in the first opening, the first electrode including metal oxide; forming a variable resistance layer along a surface of the first electrode; forming an electrode pillar along a surface of the variable resistance layer; and replacing the sacrificial layers with electrode plates.

### BRIEF DESCRIPTION OF THE DRAWINGS

FIGS. 1A and 1B are diagrams for describing the structure and the operation of a semiconductor device in accordance with an embodiment.

FIGS. 2A to 2C are diagrams for describing the structure of a semiconductor device in accordance with an embodiment.

FIGS. 3A and 3B are diagrams for describing the structure of a semiconductor device in accordance with an embodiment.

FIG. 4 is a diagram for describing the structure of a semiconductor device in accordance with an embodiment.

FIGS. 5A to 5G are diagrams for describing a manufacturing method of a semiconductor device in accordance with an embodiment.

FIGS. 6A to 6C are diagrams for describing a manufacturing method of a semiconductor device in accordance with an embodiment.

FIGS. 7A to 7G are diagrams for describing a manufacturing method of a semiconductor device in accordance with an embodiment

### DETAILED DESCRIPTION

Various embodiments are directed to a semiconductor device having a stable structure and improved characteristics and a manufacturing method of the semiconductor device.

It is possible to improve the degree of integration, operating characteristics, and reliability of a semiconductor device.

Hereafter, embodiments in accordance with the technical spirit of the present disclosure will be described with reference to the accompanying drawings.

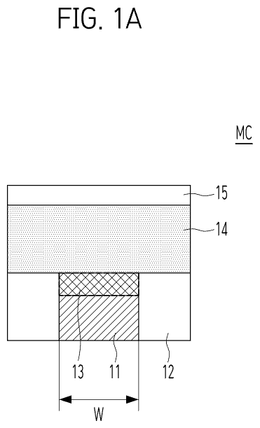

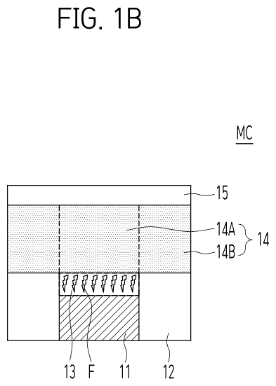

FIGS. 1A and 1B are diagrams for describing the structure and the operation of a semiconductor device in accordance with an embodiment.

Referring to FIG. 1A, the semiconductor device may include a memory cell MC. The memory cell MC may include a first electrode 13, a variable resistance layer 14, and a second electrode 15. The semiconductor device may further include an electrode plate 11 and insulating layers 12.

The electrode plate 11 may be located between the insulating layers 12. The electrode plate 11 may be an access line, a row line, or a column line. The electrode plate 11 may include metal such as tungsten.

The first electrode 13 may be located between the insulating layers 12. The first electrode 13 may be located on or over the electrode plate 11, and may be electrically connected to the electrode plate 11. The first electrode 13 and the electrode plate 11 may have substantially the same width W. The first electrode 13 may include metal oxide. The metal oxide may be a switching material whose resistance is changed by generation and dissipation of a conductive filament. As an example, the metal oxide may include one or more of the following: tungsten oxide, titanium oxide, or hafnium oxide.

The variable resistance layer 14 may be located on or over the first electrode 13. The variable resistance layer 14 may extend to upper surfaces of the insulating layers 12. The variable resistance layer 14 may have characteristics that it reversibly transitions between different resistance states depending on a voltage or a current applied to the memory cell MC. As an example, when the variable resistance layer 14 has a low resistance state, data ‘1’ may be stored, and when the variable resistance layer 14 has a high resistance state, data ‘0’ may be stored.

As an example, the variable resistance layer 14 may include a resistive material. An electrical path (or conductive path) is generated or dissipated in the variable resistance layer 14 to control its resistance state, such that data ‘1’ or ‘0’ may be stored. As an example, the variable resistance layer 14 may include transition metal oxide or include metal oxide such as a perovskite-based material.

As an example, the variable resistance layer 14 may have a magnetic tunnel junction (MTJ) structure including a magnetization pinned layer, a tunnel barrier layer, and a magnetization free layer. The data may be stored according to a change in magnetization direction of the magnetization free layer with respect to a magnetization direction of the magnetization pinned layer. As an example, the magnetization pinned layer and the magnetization free layer may each include a magnetic material, and the tunnel barrier layer may include metal oxide.

As an example, the variable resistance layer 14 may include a phase change material or include a chalcogenide-based material. The variable resistance layer 14 may change its phase according to a program operation. As an example, the variable resistance layer 14 may have a low resistance crystalline state through a set operation. As an example, the variable resistance layer 14 may have a high resistance amorphous state through a reset operation. Accordingly, the data may be stored in the memory cell using a resistance difference depending on a phase of the variable resistance layer 14.

As an example, the variable resistance layer 14 may include a variable resistance material whose resistance changes without a phase change or include a chalcogenide-based material. The variable resistance layer 14 may maintain its phase after the program operation. As an example, the variable resistance layer 14 may have an amorphous state, and may maintain the amorphous state without changing to a crystalline state after the program operation. A threshold voltage of the memory cell may be changed depending on a program voltage applied to the memory cell, and the memory cell may be programmed to at least two states. As an example, the memory cell may be programmed to a set state or a reset state using program voltages having different polarities. Accordingly, the data may be stored in the memory cell using a difference in the threshold voltage of the memory cell.

The second electrode 15 may be located on or over the variable resistance layer 14. The second electrode 15 may extend along a surface of the variable resistance layer 14. The second electrode 15 may include polysilicon, tungsten (W), tungsten nitride (WNx), tungsten silicide (WSix), titanium (Ti), titanium nitride (TiNx), titanium silicon nitride (TiSiN), titanium aluminum nitride (TiAIN), tantalum (Ta), tantalum nitride (TaN), tantalum silicon nitride (TaSiN), tantalum aluminum nitride (TaAIN), carbon (C), silicon carbide (SiC), silicon carbonitride (SiCN), aluminum (AI), copper (Cu), zinc (Zn), nickel (Ni), cobalt (Co), lead (Pb), platinum (Pt), molybdenum (Mo), ruthenium (Ru), or the like, or include combinations thereof.

Referring to FIG. 1B, the first electrode 13 may include a conductive filament F. During the manufacture of the semiconductor device, the first electrode 13 may be activated through a firing operation, and the filament F may be generated in the first electrode 13. The filament F may provide electrical paths between the electrode plate 11 and the variable resistance layer 14. Accordingly, an electric field may be concentrated on the filament F in the first electrodes 13, and an effective area of the first electrode 13 may be reduced.

The variable resistance layer 14 may include a first portion 14A and a second portion 14B. The first portion 14A may be a region where a resistance change occurs when the memory cell MC operates, and may be an active region. The first portion 14A may have an area corresponding to the first electrode 13. The second portion 14B may be a region where a resistance change does not occur substantially, and may be an inactive region. As the effective area of the first electrode 13 is reduced by the filament F, an effective area of the variable resistance layer 14 may also be reduced.

According to the structure described above, the first electrode 13 exists between the variable resistance layer 14 and the electrode plate 11. Accordingly, it is possible to reduce or prevent diffusion of a material of the electrode plate 11 into the variable resistance layer 14. In addition, the first electrode 13 may include the metal oxide, and an operating area of the memory cell MC may be reduced by the filament F generated in the first electrode 13.

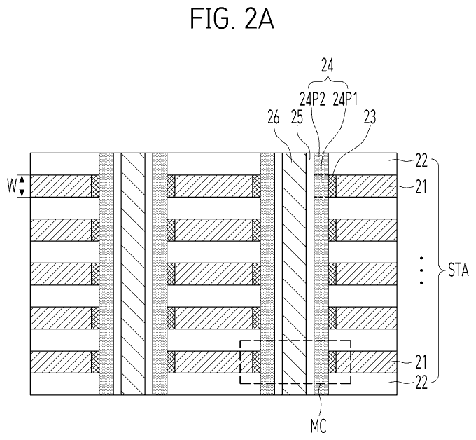

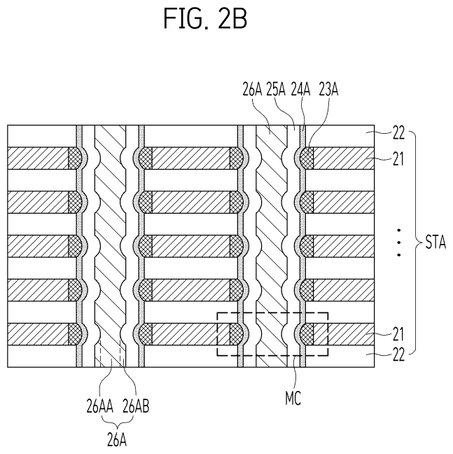

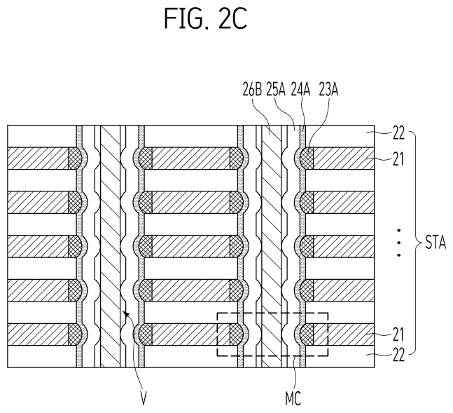

FIGS. 2A to 2C are diagrams for describing the structure of a semiconductor device in accordance with an embodiment. Hereinafter, the content overlapping with the previously described content may be omitted.

Referring to FIG. 2A, the semiconductor device may include a stack STA, a first electrode 23, a variable resistance layer 24, a second electrode 25, and an electrode pillar 26.

The stack STA may include electrode plates 21 and insulating layers 22 that are alternately stacked. The electrode plates 21 may be row lines or column lines, and may each include metal such as tungsten. The insulating layers 22 are used to insulate the stacked electrode plates 21 from each other, and may each include an insulating material such as oxide, nitride, or air gap.

The electrode pillar 26 may extend through the stack STA. As an example, the electrode pillar 26 may penetrate through the stack STA in a stacking direction, and the stacking direction may be a vertical direction. The electrode pillar 26 may be electrically connected to the column lines or the row lines. As an example, the electrode plates 21 may be the row lines, and the electrode pillar 26 may be electrically connected to the column lines. The electrode pillar 26 may include a conductive material such as polysilicon or metal.

The variable resistance layer 24 may surround sidewalls of the electrode pillar 26. The variable resistance layer 24 may extend along surfaces of the electrode pillar 26. In an embodiment, the variable resistance layer 24 extends through the electrode plates 21 and the insulating layers 22. In an embodiment, the variable resistance layer 24 extends through a plurality memory cells MC and are shared by the memory cells. The variable resistance layer 24 may include first portions 24P1 located between the electrode plates 21 and the electrode pillar 26 and second portions 24P2 located between the insulating layers 22 and the electrode pillar 26. The first portions 24P1 and the second portions 24P2 may be alternately arranged. The first portions 24P1 may be active regions where resistance changes, and the second portions 24P2 may be inactive regions where resistance does not change substantially.

The first electrodes 23 may be located between the electrode plates 21 and the variable resistance layer 24, respectively. The first electrodes 23 may be located between the stacked insulating layers 22, and may be separated from each other by the insulating layers 22. The first electrodes 23 may each have substantially the same width W as the electrode plates 21.

The second electrode 25 may be located between the electrode pillar 26 and the variable resistance layer 24. The second electrode 25 may surround the sidewalls of the electrode pillar 26. The second electrode 25 may include a different material from the first electrode 23. As an example, the second electrode 25 may include carbon.

Referring to FIG. 2B, the semiconductor device may include a stack STA, a first electrode 23A, a variable resistance layer 24A, a second electrode 25A, and an electrode pillar 26A.

The first electrodes 23A may protrude toward the electrode pillar 26A compared to the insulating layers 22. Surfaces of the first electrodes 23A in contact with (or proximate to) the variable resistance layer 24A may include curved surfaces. The variable resistance layer 24A may extend along surfaces of the insulating layers 22 and the surfaces of the first electrodes 23A, and may have a cross section with an irregular shape. The second electrode 25A may extend along a surface of the variable resistance layer 24A, and may have a cross section with an irregular shape.

The electrode pillar 26A may extend through the stack STA, and may penetrate through the stack STA in the vertical direction. The second electrode 25A may surround sidewalls of the electrode pillar 26A. The electrode pillar 26A may include a penetration portion 26AA and at least one protrusion portion 26AB. The penetration portion 26AA may extend through the stack STA, and may penetrate through the stack STA in the vertical direction. The protrusion portions 26AB may protrude from sidewalls of the penetration portion 26AA toward the insulating layers 22. The protrusion portions 26AB may be located at levels corresponding to the insulating layers.

Referring to FIG. 2C, the semiconductor device may include a stack STA, a first electrode 23A, a variable resistance layer 24A, a second electrode 25A, and an electrode pillar 26B. The semiconductor device may further include at least one void V. The void V may be located between the electrode pillar 26B and the second electrode 25A. The void V may be located at a level corresponding to the insulating layer 22.

According to the structure described above, memory cells MC may be respectively located in regions where the electrode plates 21 and the electrode pillar 26, 26A, or 26B intersect each other. The memory cells MC may be resistive memory cells, and may be stacked along the electrode pillar 26, 26A, or 26B. Each of the memory cells MC may include the first electrode 23, the variable resistance layer 24 or 24A, and the second electrode 25 or 25A.

The memory cells MC adjacent to each other in the stacking direction may share the variable resistance layer 24 or 24A with each other. The memory cells MC adjacent to each other in the stacking direction may include the first electrodes 23, respectively, and the first electrodes 23 may be separated from each other. The memory cells MC adjacent to each other in the stacking direction may not share the first electrodes 23. Even though the memory cells MC share the variable resistance layer 24 or 24A with each other, the active regions and the inactive regions are defined in the variable resistance layer 24 or 24A by the first electrodes 23 separated from each other. Because the inactive region exists between the active regions, the movement of elements between the active regions may be reduced. As an example, the movement of selenium (Se) between the stacked memory cells MC may be reduced. Accordingly, a phenomenon in which a threshold voltage of the memory cell MC fluctuates due to the movement of the elements within the variable resistance layer 24 or 24A may be improved.

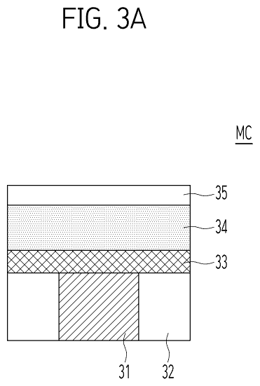

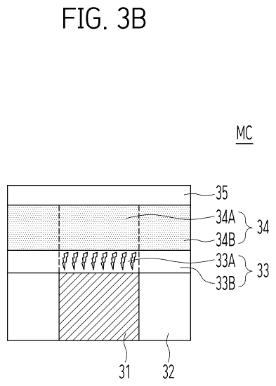

FIGS. 3A and 3B are diagrams for describing the structure of a semiconductor device in accordance with an embodiment.

Referring to FIG. 3A, the semiconductor device may include a memory cell MC. The memory cell MC may include a first electrode 33, a variable resistance layer 34, and a second electrode 35. The semiconductor device may further include an electrode plate 31 and insulating layers 32.

The electrode plate 31 may be located between the insulating layers 32. The first electrode 33 may be located on or over the electrode plate 31, and may extend to upper surfaces of the insulating layers 32. The first electrode 33 may include metal oxide. The metal oxide may be a switching material whose resistance is changed by generation and dissipation of a conductive filament. As an example, the metal oxide may include one or more of the following: of tungsten oxide, titanium oxide, and hafnium oxide.

The variable resistance layer 34 may be located on the first electrode 33. The variable resistance layer 34 may extend along a surface of the first electrode 33. The second electrode 35 may be located on or over the variable resistance layer 34. The second electrode 35 may extend along a surface of the variable resistance layer 34.

Referring to FIG. 3B, the first electrode 33 may include a first portion 33A and a second portion 33B. The first portion 33A may be a portion that overlaps with the electrode plate 31, and may include a conductive filament F. The second portion 33B may be a portion that does not overlap with the electrode plate 31, and may not include the conductive filament F. The filament F may be generated by a firing operation in a manufacturing process of the semiconductor device. The filament F may provide electrical paths between the electrode plate 31 and the variable resistance layer 34. The first portion 33A in which the filament F is generated may have lower resistivity than the second portion 33B in which the filament F is not generated. Accordingly, the first portion 33A of the first electrode 33 in which the filament F is formed may serve as a substantial electrode, and an electric field may be concentrated on the filament F, such that an effective area of the first electrode 33 may be reduced.

The variable resistance layer 34 may include a first portion 34A and a second portion 34B. The first portion 34A may be a region where a resistance change occurs when the memory cell MC operates, and may be an active region. The first portion 34A may have an area corresponding to the first portion 33A of the first electrode 33. The second portion 34B may be a region where a resistance change does not occur, and may be an inactive region. As the effective area of the first electrode 33 is reduced by the filament F, an effective area of the variable resistance layer 34 may also be reduced.

According to the structure described above, the first electrode 33 may include the metal oxide, and the filament F may be generated in a partial region of the first electrode 33. Accordingly, an operating area of the memory cell MC may be reduced.

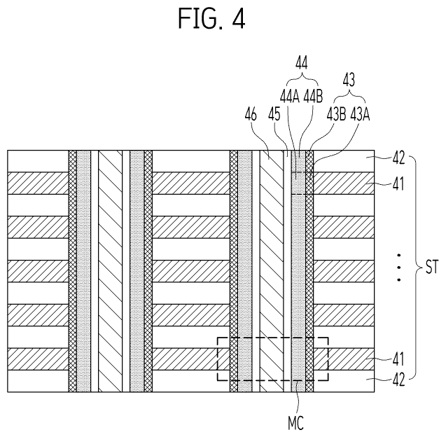

FIG. 4 is a diagram for describing the structure of a semiconductor device in accordance with an embodiment. Hereinafter, the content overlapping with the previously described content may be omitted.

Referring to FIG. 4, the semiconductor device may include a stack ST, a first electrode 43, a variable resistance layer 44, a second electrode 45, and an electrode pillar 46.

The stack ST may include electrode plates 41 and insulating layers 42 that are alternately stacked. The electrode pillar 46 may extend through the stack ST. As an example, the electrode plates 41 may be row lines, and the electrode pillar 46 may be electrically connected to column lines.

The variable resistance layer 44 may be provided over a sidewall of the electrode pillar 46. The variable resistance layer 44 may surround sidewalls of the electrode pillar 46. The variable resistance layer 44 may extend along surfaces of the electrode pillar 46. The variable resistance layer 44 may include first portions 44A located between the electrode plates 41 and the electrode pillar 46 and second portions 44B located between the insulating layers 42 and the electrode pillar 46. The first portions 44A and the second portions 44B may be alternately arranged. The first portions 44A may be active regions where resistance changes, and the second portions 44B may be inactive regions where resistance does not change.

The first electrode 43 may be provided over the variable resistance layer 44. The first electrode 43 may surround the variable resistance layer 44, and may extend along outer walls of the variable resistance layer 44. The first electrode 43 may include first portions 43A located between the variable resistance layer 44 and the electrode plates 41 and second portions 43B located between the variable resistance layer 44 and the insulating layers 42. The first portions 43A and the second portions 43B may be alternately arranged. The first portions 43A may be located to correspond to the first portions 44A, and the second portions 43B may be located to correspond to the second portions 44B. The first portions 43A may be active regions that include filaments, and the second portions 43B may be inactive regions that do not include the filaments. The first portions 43A may have lower resistivity than the second portions 43B.

The second electrode 45 may be located between the electrode pillar 46 and the variable resistance layer 44. The second electrode 45 may surround the sidewalls of the electrode pillar 46. The second electrode 45 may include carbon.

According to the structure described above, memory cells MC may be respectively located in regions where the electrode plates 41 and the electrode pillar 46 intersect each other. The memory cells MC may be stacked along the electrode pillar 46 and the electrode pillar 46 may extend through the memory cells MC. Each of the memory cells MC may include the first electrode 43, the variable resistance layer 44, and the second electrode 45.

The memory cells MC adjacent to each other in the stacking direction may share the variable resistance layer 44 and the first electrode 43 with each other. Even though the memory cells MC share the variable resistance layer 44 with each other, the active regions and the inactive regions are defined in the variable resistance layer 44. Because the inactive region exists between the active regions, the movement of elements between the active regions may be reduced. As an example, the movement of selenium (Se) between the stacked memory cells MC may be reduced. Accordingly, a phenomenon in which a threshold voltage of the memory cell MC fluctuates due to the movement of the elements within the variable resistance layer 44 may be improved.

Even though the memory cells MC share the first electrode 43 with each other, the active regions and the inactive regions are defined in the first electrode 43. Because the active region in which the filament is formed serves as a substantial electrode and an electric field is concentrated on the filament, an effective area of the first electrode 43 may be reduced.

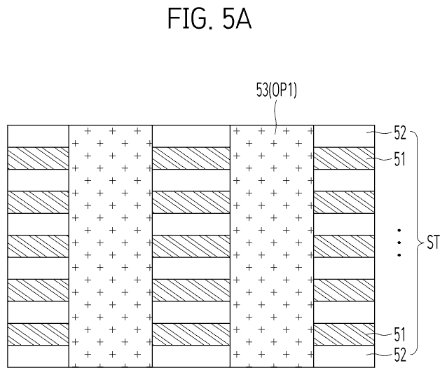

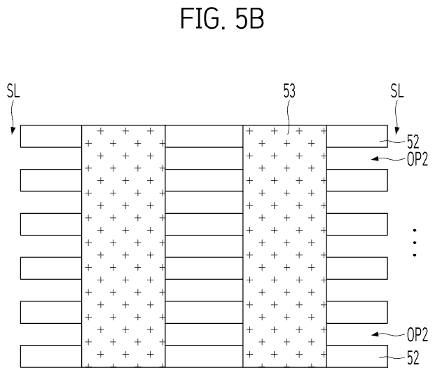

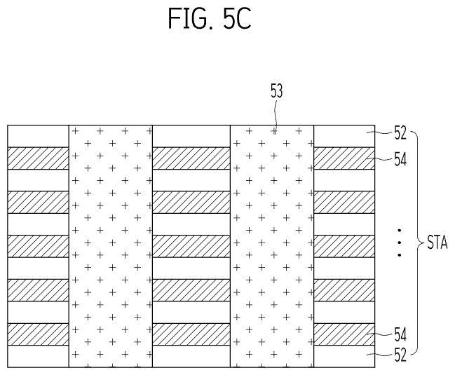

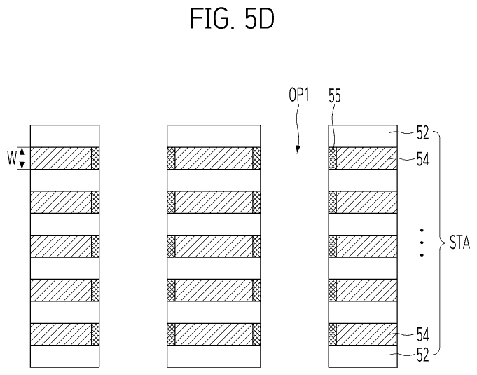

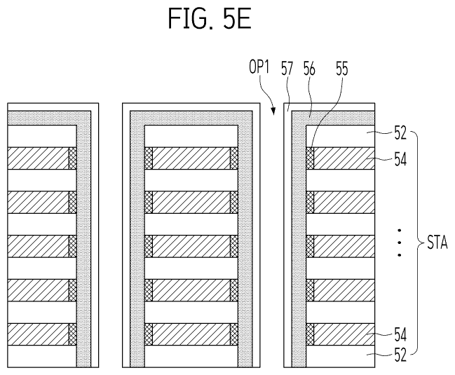

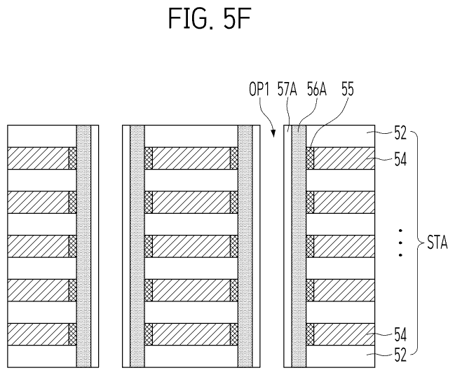

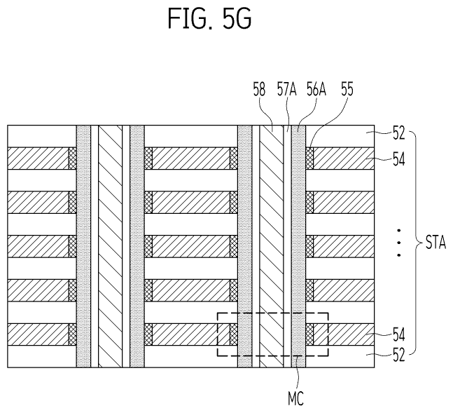

FIGS. 5A to 5G are diagrams for describing a manufacturing method of a semiconductor device in accordance with an embodiment. Hereinafter, the content overlapping with the previously described content may be omitted.

Referring to FIG. 5A, a stack ST including first sacrificial layers 51 and insulating layers 52 that are alternately stacked may be formed. The first sacrificial layers 51 may each include a material having a high etching selectivity with respect to the insulating layers 52. The first sacrificial layers 51 are used to secure spaces in which electrode plates are to be formed, and may each include a sacrificial material such as nitride. The insulating layers 52 may each include an insulating material such as oxide.

Subsequently, a first opening OP1 extending through the stack ST may be formed. The first opening OP1 may penetrate through the stack ST in the stacking direction. Subsequently, a second sacrificial layer 53 may be formed in the first opening OP1. The second sacrificial layer 53 may extend through the first sacrificial layers 51 and the insulating layers 52. The second sacrificial layer 53 may penetrate through the first sacrificial layers 51 and the insulating layers 52 in the stacking direction. The second sacrificial layer 53 may include a material having an etching selectivity with respect to the first sacrificial layer 51 and the insulating layer 52.

Referring to FIG. 5B, second openings OP2 may be formed by removing the first sacrificial layers 51. As an example, a slit SL penetrating through the stack ST may be formed, and the first sacrificial layers 51 may be selectively etched through the slit SL. Through this, the second openings OP2 may be defined between the stacked insulating layers 52, and the second sacrificial layer 53 may be exposed through the second openings OP2. The remaining insulating layers 52 may be supported by the second sacrificial layer 53.

Referring to FIG. 5C, electrode plates 54 may be formed in the second openings OP2, respectively. As an example, the electrode plates 54 may be formed by filling the second openings OP2 with metal such as tungsten. Through this, a stack STA including the electrode plates 54 and the insulating layers 52 that are alternately stacked may be formed.

Referring to FIG. 5D, the first opening OP1 may be formed by removing the second sacrificial layer 53. That is, the first opening OP1 may be reopened. Subsequently, first electrodes 55 may be formed by oxidizing surfaces of the electrode plates 54 exposed through the first opening OP1. The surfaces of the electrode plates 54 may be selectively oxidized, and the first electrodes 55 may be formed in a self-aligned manner. The first electrodes 55 may each have substantially the same width W as the electrode plates 54.

Depending on an oxidation condition, the first electrodes 55 may protrude into the first opening OP1 or sidewalls of the first electrodes 55 may be aligned with sidewalls of the insulating layers 52.

The first electrodes 55 may be formed by oxidizing metal layers, and may each include metal oxide. The resistivity of the first electrodes 55 may be determined according to an oxidation degree of the metal layers. The metal oxide may be a resistive switching material. As an example, the metal oxide may include one or more of the following: tungsten oxide, titanium oxide, and hafnium oxide.

Referring to FIG. 5E, a variable resistance material layer 56 may be formed in the first opening OP1. The variable resistance material layer 56 may be formed along inner walls of the first opening OP1, and may extend along an upper surface of the stack STA. The variable resistance material layer 56 may be in contact with the first electrodes 55. Subsequently, a second electrode layer 57 may be formed along a surface of the variable resistance material layer 56. The second electrode layer 57 may be in contact with the variable resistance material layer 56.

Referring to FIG. 5F, a second electrode 57A and a variable resistance layer 56A may be formed by etching the second electrode layer 57 and the variable resistance material layer 56. As an example, portions of the second electrode layer 57 and the variable resistance material layer 56 formed on the upper surface of the stack STA may be etched by performing an etch-back process. Through this, the variable resistance layer 56A and the second electrode 57A may be formed on the inner walls of the first opening OP1. The second electrode 57A may include carbon.

Referring to FIG. 5G, an electrode pillar 58 may be formed in the first opening OP1. As an example, a conductive layer may be formed to fill the first opening OP1. The conductive layer may also be formed on an upper surface of the stack STA, and may include metal such as tungsten. Subsequently, the electrode pillar 58 may be formed by planarizing the conductive layer until the upper surface of the stack STA is exposed. A chemical mechanical polish (CMP) process may be used as a planarization process.

For reference, it is also possible to combine a process of planarizing the conductive layer with the etching process described above. As an example, the etching process described with reference to FIG. 5F may be omitted. In such a case, the conductive layer may be formed on the second electrode layer 57. Subsequently, the electrode pillar 58, the second electrode 57A, and the variable resistance layer 56A may be formed by etching the conductive layer, the second electrode layer 57, and the variable resistance material layer 56 until the surface of the stack STA is exposed.

Through this, memory cells MC may be respectively formed in regions where the electrode plates 54 and the electrode pillar 58 intersect each other. The memory cells MC may include the first electrodes 55, respectively, and may share the variable resistance layer 56A with each other.

Subsequently, the first electrodes 55 may be activated. As an example, the first electrodes 55 may be activated by performing a firing operation to apply a strong electrical stimulus to the memory cells MC. During the firing operation, a firing current having a great current amount may be applied to the memory cells MC. The firing current may cause breakdown of or damage to the first electrodes 55 having a relatively small thickness, and may generate filaments in the first electrodes 55. The filaments generated by the firing operation may be maintained in the first electrodes 55 regardless of a set operation and/or a reset operation of the memory cells MC.

According to the manufacturing method described above, the first electrodes 55 may be formed by selectively oxidizing the surfaces of the electrode plates 54 through the first opening OP1. Accordingly, the first electrodes 55 separated from each other may be formed in the self-aligned manner.

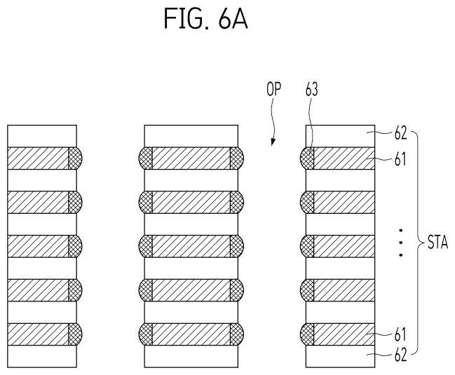

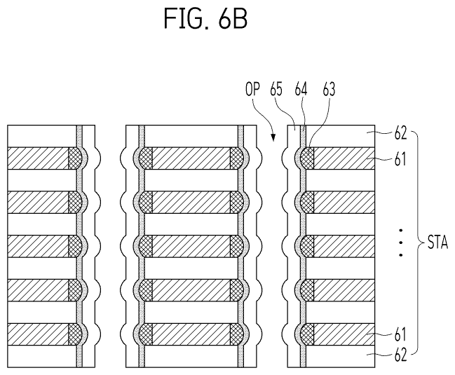

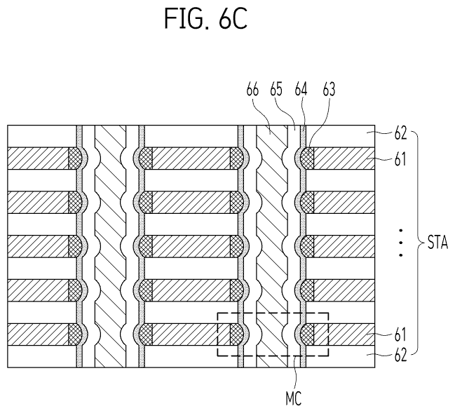

FIGS. 6A to 6C are diagrams for describing a manufacturing method of a semiconductor device in accordance with an embodiment. Hereinafter, the content overlapping with the previously described content may be omitted.

Referring to FIG. 6A, a stack STA including electrode plates 61 and insulating layers 62 that are alternately stacked may be formed. The stack STA may include an opening OP, and the opening OP may extend through the stack STA. A method of forming the stack STA including the opening OP may be similar to that of the embodiment described above with reference to FIGS. 5A to 5C.

Subsequently, first electrodes 63 may be formed by oxidizing surfaces of the electrode plates 61 exposed through the opening OP. During an oxidation process, the first electrodes 63 may be expanded, and the first electrodes 63 may protrude into the opening OP. Sidewalls of the first electrodes 63 may be located closer to the center of the opening OP than sidewalls of the insulating layers 62 are. Inner walls of the opening OP may have irregularities.

Referring to FIG. 6B, a variable resistance layer 64 may be formed in the opening OP. As an example, the variable resistance layer 64 may be formed by a deposition method having good step coverage, and may be deposited by an atomic layer deposition (ALD) method. The variable resistance layer 64 may be formed along a profile of the protruding first electrodes 63, and an irregular shape due to the protruding first electrodes 63 may be transferred to the variable resistance layer 64. Accordingly, a surface of the variable resistance layer 64 may have irregularities.

Subsequently, a second electrode 65 may be formed along a surface of the variable resistance layer 64. The second electrode 65 may be formed by a deposition method having good step coverage, and may be deposited by an ALD method. The second electrode 65 may be formed along a profile of the variable resistance layer 64, and an irregular shape of the variable resistance layer 64 may be transferred to the second electrode 65. Accordingly, a surface of the second electrode 65 may have irregularities.

Referring to FIG. 6C, an electrode pillar 66 may be formed in the opening OP. The electrode pillar 66 may be formed to fill the opening OP. As an example, a conductive material may be deposited along a profile of the second electrode 65 by a deposition method having relatively good step coverage. As an example, the conductive material may be deposited by a chemical vapor deposition (CVD) method to fill the irregularities of the second electrode 65. In such a case, the electrode pillar 66 including a penetration portion and protrusion portions may be formed. As another example, the conductive material may be deposited by a method having relatively poor step coverage. As an example, the conductive material may be deposited by a physical vapor deposition (PVD) method, and may not be completely filled in the irregularities. In such a case, voids V may be formed between the second electrode 65 and the electrode pillar 66. The voids may be located at levels corresponding to the insulating layers 62.

Subsequently, a firing operation may be performed. Filaments may be generated in the first electrodes 63 through the firing operation. As an example, the filaments may be generated in metal oxide layers. The generated filaments may be maintained regardless of operations of memory cells MC.

According to the manufacturing method described above, the first electrodes 63 may be formed by selectively oxidizing the surfaces of the electrode plates 61 through the opening OP. Accordingly, the first electrodes 63 separated from each other may be formed in a self-aligned manner.

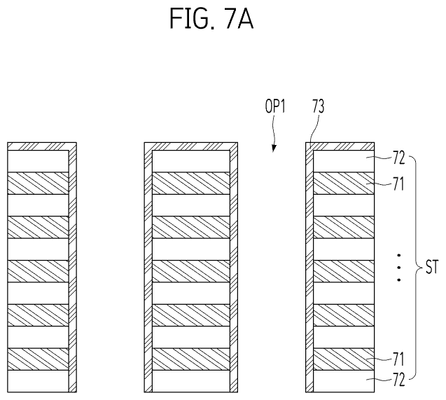

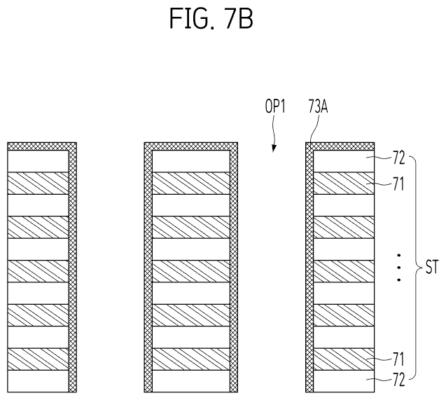

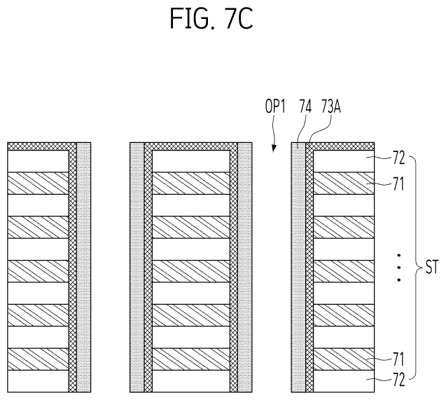

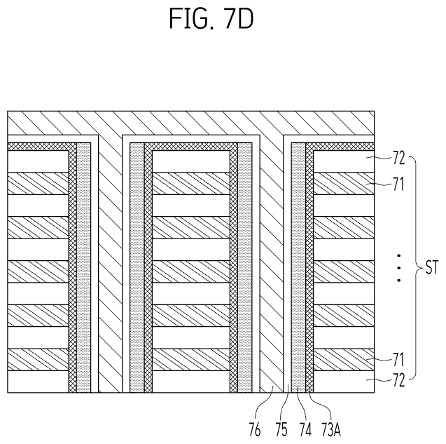

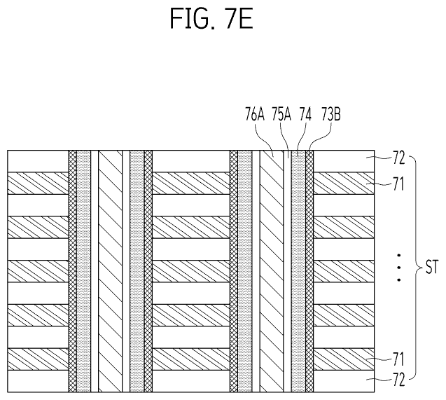

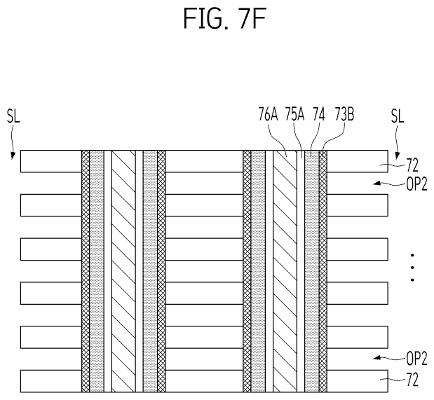

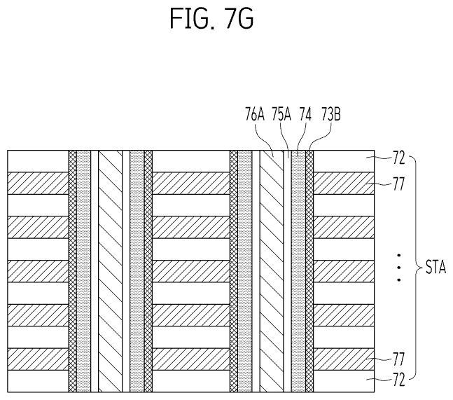

FIGS. 7A to 7G are diagrams for describing a manufacturing method of a semiconductor device in accordance with an embodiment. Hereinafter, the content overlapping with the previously described content may be omitted.

Referring to FIG. 7A, a stack ST including sacrificial layers 71 and insulating layers 72 that are alternately stacked may be formed. The sacrificial layers 71 may each include a material having a high etching selectivity with respect to the insulating layers 72. The sacrificial layers 71 are used to secure spaces in which electrode plates are to be formed, and may each include a sacrificial material such as nitride. The insulating layers 72 may each include an insulating material such as oxide.

Subsequently, a first opening OP1 extending through the stack ST may be formed. The first opening OP1 may penetrate through the stack ST in the stacking direction. Subsequently, a seed layer 73 may be formed in the first opening OP1. The seed layer 73 may be formed along inner walls of the first opening OP1, and may extend along an upper surface of the stack ST. The seed layer 73 is used to form a first electrode, and may include metal such as tungsten, titanium, or hafnium.

Referring to FIG. 7B, a first electrode layer 73A may be formed by oxidizing the seed layer 73. The first electrode layer 73A may be formed along the inner walls of the first opening OP1, and may extend along the upper surface of the stack ST. The first electrode layer 73A may include metal oxide, and may be a resistance switching material. As an example, the metal oxide may include one or more of the following: tungsten oxide, titanium oxide, or hafnium oxide.

For reference, it is also possible to directly deposit the first electrode layer 73A without forming the seed layer 73. The first electrode layer 73A may be deposited along the inner walls of the first opening OP1 and the upper surface of the stack ST. As an example, a metal oxide layer may be directly deposited.

Referring to FIG. 7C, a variable resistance layer 74 may be formed in the first electrode layer 73A. As an example, a variable resistance material layer may be formed along a surface of the first electrode layer 73A. The variable resistance material layer may be formed not only in the first opening OP1 but also on the upper surface of the stack ST. Subsequently, a portion of the variable resistance material layer formed on the upper surface of the stack ST may be etched by performing an etch-back process. Through this, the variable resistance layer 74 located in the first opening OP1 may be formed. In a process of performing the etch-back process, the first electrode layer 73A formed on the upper surface of the stack ST may also be at least partially etched.

Referring to FIG. 7D, a second electrode layer 75 may be formed along a surface of the variable resistance layer 74. The second electrode layer 75 may be formed in the first opening OP1, and may extend to the upper surface of the stack ST. The second electrode layer 75 may include carbon.

Subsequently, a conductive layer 76 may be formed in the second electrode layer 75. The conductive layer 76 is used to form an electrode pillar, and may include metal such as tungsten. The conductive layer 76 may fill the first opening OP1, and may also be formed on the upper surface of the stack ST.

Referring to FIG. 7E, an electrode pillar 76A may be formed in the first opening OP1. As an example, the electrode pillar 76A, a second electrode 75A, and a first electrode 73B may be formed by planarizing the conductive layer 76, the second electrode layer 75, and the first electrode layer 73A until the upper surface of the stack ST is exposed. A CMP process may be used as a planarization process.

For reference, it is also possible to combine a process of planarizing the conductive layer 76 with the etching process described above. As an example, in FIG. 7C, the variable resistance material layer may be formed along the inner walls of the first opening OP1 and the upper surface of the stack ST. In such a case, the electrode pillar 76A, the second electrode 75A, the variable resistance layer 74, and the first electrode 73B may be formed by etching the conductive layer 76, the second electrode layer 75, the variable resistance material layer, and the first electrode layer 73A until the surface of the stack ST is exposed.

Referring to FIG. 7F, second openings OP2 may be formed by removing the sacrificial layers 71. As an example, a slit SL penetrating through the stack ST may be formed, and the sacrificial layers 71 may be selectively etched through the slit SL. Through this, the second openings OP2 may be defined between the stacked insulating layers 72, and the first electrode 73B may be exposed through the second openings OP2. The remaining insulating layers 72 may be supported by the electrode pillar 76A.

Referring to FIG. 7G, electrode plates 77 may be formed in the second openings OP2, respectively. As an example, the electrode plates 77 may be formed by filling the second openings OP2 with metal such as tungsten. Through this, a stack STA including the electrode plates 77 and the insulating layers 72 that are alternately stacked may be formed.

Subsequently, a firing operation may be performed. The first electrode 73B may be locally activated through the firing operation. Filaments may be formed only in regions of the first electrode 73B where the electrode plates 77 and the electrode pillar 76A intersect each other. The filaments may be formed locally in the metal oxide layer, and a corresponding portion may be used as an electrode.

According to the manufacturing method described above, the first electrode 73B including the metal oxide may be formed in the first opening OP1. When a memory cell operates, a portion of the first electrode 73B located between the variable resistance layer 74 and the electrode plate 77 may serve as a substantial electrode, and the remaining portion of the first electrode 73B may be an inactive region.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a stack including electrode plates and insulating layers that are alternately stacked;
an electrode pillar extending through the stack;
a variable resistance layer provided over a sidewall of the electrode pillar and extending through the electrode plates and the insulating layers; and
first electrodes located between the electrode plates and the variable resistance layer, respectively, and each first electrode including metal oxide.

2. The semiconductor device of claim 1, wherein the first electrodes each include a conductive filament.

3. The semiconductor device of claim 2, wherein the conductive filament provides a conductive path between the electrode plate and the variable resistance layer.

4. The semiconductor device of claim 1, wherein the metal oxide includes one or more of the following: tungsten oxide, titanium oxide, or hafnium oxide.

5. The semiconductor device of claim 1, further comprising a second electrode located between the electrode pillar and the variable resistance layer.

6. The semiconductor device of claim 5, wherein the second electrode includes carbon.

7. The semiconductor device of claim 1, wherein each of the first electrodes has substantially the same width as that of a corresponding electrode plate.

8. The semiconductor device of claim 1, wherein the first electrodes protrude more toward the electrode pillar compared to the insulating layers.

9. The semiconductor device of claim 8, wherein the variable resistance layer has a cross section with an irregular shape.

10. The semiconductor device of claim 8, further comprising a second electrode located between the electrode pillar and the variable resistance layer and having a cross section with an irregular shape.

11. The semiconductor device of claim 8, further comprising:
a second electrode located between the electrode pillar and the variable resistance layer; and
at least one void located between the electrode pillar and the second electrode.

12. The semiconductor device of claim 8, wherein the electrode pillar comprises:
a penetration portion extending through the stack; and
at least one protrusion portion protruding from a sidewall of the penetration portion.

13. The semiconductor device of claim 1, further comprising:
a plurality of memory cells that share the variable resistance layer, each memory cell being defined at a region where one of the electrode plates and the electrode pillar intersect each other.

14. The semiconductor device of claim 13, wherein the memory cells include the first electrodes, respectively, and the first electrodes are separated from each other.

15. A semiconductor device, comprising:
a plurality of memory cells that are stacked along a direction;
an electrode pillar extending along the direction and through the plurality of the memory cells;
a variable resistance layer provided over a sidewall of the electrode pillar and shared by the memory cells, the variable resistance layer extending between the first and the second electrodes of the memory cells; and
a first electrode provided over the variable resistance layer and shared by the memory cells, wherein the first electrode includes metal oxide.

16. The semiconductor device of claim 15, wherein the first electrode includes a conductive filament.

17. The semiconductor device of claim 16, wherein the conductive filament provides a conductive path between the electrode plate and the variable resistance layer.

18. The semiconductor device of claim 16, wherein the conductive filament is located in an intersection region between the electrode plate and the electrode pillar.

19. The semiconductor device of claim 15, wherein the metal oxide includes one or more of the following: tungsten oxide, titanium oxide, or hafnium oxide.

20. The semiconductor device of claim 15, further comprising a second electrode located between the electrode pillar and the variable resistance layer.

21. The semiconductor device of claim 20, wherein the second electrode includes carbon.

22. The semiconductor device of claim 15, wherein the memory cells are respectively located in regions where the electrode plates and the electrode pillar intersect each other.

23. The semiconductor device of claim 15, wherein the memory cells are respectively located in regions where the electrode plates and the electrode pillar intersect each other, and share the first electrode with each other.

24. A method for manufacturing a semiconductor device, the method comprising:
forming a stack including electrode plates and insulating layers that are alternately stacked;
forming a first opening extending through the stack to expose the electrode plates;
forming first electrodes on or over the exposed electrode plates, the first electrodes each including metal oxide;
forming a variable resistance layer in the first opening; and
forming an electrode pillar in the variable resistance layer.

25. The method of claim 24, wherein the first electrodes are formed by oxidizing the exposed electrode plates.

26. The method of claim 24,
wherein the forming of the stack comprises:
alternately stacking first sacrificial layers and the insulating layers;
forming a second sacrificial layer extending through the first sacrificial layers and the insulating layers;
removing the first sacrificial layers to form second openings; and
forming the electrode plates in the second openings, respectively.

27. The method of claim 26, wherein the first opening is formed by removing the second sacrificial layer.

28. The method of claim 24, wherein the first electrodes protrude into the first opening, and the variable resistance layer is formed along a profile of the protruding first electrodes.

29. The method of claim 24, further comprising forming a second electrode along the surface of the variable resistance layer.

30. The method of claim 29, the variable resistance layer has an irregular shape, and the second electrode is formed along a profile of the variable resistance layer.

31. The method of claim 29, wherein the second electrode includes carbon.

32. The method of claim 24, wherein the electrode pillar including at least one protrusion portion located to correspond to the insulating layers is formed by depositing a conductive material so as to fill irregularities of the second electrode.

33. The method of claim 24, further comprising forming at least one void between the electrode pillar and the second electrode at a level corresponding to each of the insulating layers.

34. The method of claim 24, further comprising forming conductive filaments in the first electrodes by performing a firing operation.

35. The method of claim 24, wherein the metal oxide includes one or more of the following: tungsten oxide, titanium oxide, or hafnium oxide.

36. A method for manufacturing a semiconductor device, the method comprising:
forming a stack including sacrificial layers and insulating layers that are alternately stacked;
forming a first opening extending through the stack;
forming a first electrode in the first opening, the first electrode including metal oxide;
forming a variable resistance layer along a surface of the first electrode;
forming an electrode pillar along a surface of the variable resistance layer; and
replacing the sacrificial layers with electrode plates.

37. The method of claim 36, wherein the forming of the first electrode comprises:
forming a seed layer in the first opening; and
oxidizing the seed layer to form the first electrode.

38. The method of claim 36, wherein in the forming of the first electrode, a metal oxide layer is deposited in the first opening.

39. The method of claim 36, wherein the replacing of the sacrificial layers with the electrode plates comprises:
forming second openings by removing the sacrificial layers; and
forming the electrode plates in the second openings, respectively.

40. The method of claim 36, further comprising forming a second electrode along the surface of the variable resistance layer.

41. The method of claim 40, wherein the second electrode includes carbon.

42. The method of claim 36, further comprising forming conductive filaments in regions of the first electrode where the electrode plates and the electrode pillar intersect each other by performing a firing operation.

43. The method of claim 36, wherein the metal oxide includes one or more of the following: tungsten oxide, titanium oxide, or hafnium oxide.
